(19) United States
(12) Patent Application Publication
(10) Pub. No.: US 2016/0172565 A9
(43) Pub. Date: Jun. 16, 2016

(54) In2Te3 Precipitates in Bulk Bi2Te3 for Thermoelectric Applications

(71) Applicant: California Institute of Technology, (US)

(72) Inventors: G. Jeffrey Snyder, Pasadena, CA (US); Yanzhong Pei, Alhambra, CA (US); Nicholas A. Heinz, Altadena, CA (US)

(73) Assignee: California Institute of Technology, Pasadena, CA (US)

(21) Appl. No.: 13/871,770

(22) Filed: Apr. 26, 2013

Related U.S. Application Data
(60) Provisional application No. 61/638,900, filed on Apr. 26, 2012.
(60) Provisional application No. 61/650,909, filed on May 23, 2012.

(51) Int. Cl. H01L 35/16

(52) U.S. Cl. CPC H01L 35/16

(57) ABSTRACT

The present invention teaches a successful synthesis regime to grow highly oriented plate-like In₂Te₃ nanostructures inside bulk thermoelectric Bi₂Te₃ using a thermodynamically driven nucleation and growth technique. As described herein, the inventive materials can further be doped with +2 and +4 rare earth elements, and others, in order to achieve the desired performance characteristics.

### CROSS-REFERENCE TO RELATED APPLICATIONS

This application claims priority from U.S. Provisional Patent Application No. 61/638,900, filed on Apr. 26, 2012 and U.S. Provisional Patent Application No. 61/650,909, filed on May 23, 2012, both of which are incorporated herein by reference in their entirety.

### GOVERNMENT RIGHTS

This invention was made with government support under FA9550-10-1-0533 awarded by the Air Force. The government has certain rights in the invention.

### FIELD OF INVENTION

The present invention relates to the manufacturing and use of advanced thermoelectrics.

### BACKGROUND

To make efficient thermoelectric materials, it is necessary to optimize the dimensionless figure of merit (zT). However, when optimizing the transport properties that make up zT, including the Seebeck coefficient, S, electrical conductivity, a, and both the electrical and lattice components of the thermal conductivity, Kₑ and Kₗ

$$( zT = \frac{{s}^{2} σ}{{κ}_{e} + {κ}_{l}} T ) ,$$

this often proves to be quite difficult due to the coupling of these transport properties. Although progress has been made in the field, there is a need in the art for improved thermoelectric materials for a variety of applications.

### SUMMARY OF THE INVENTION

In some embodiments, the invention teaches an article of manufacture including a matrix and embedded precipitates, wherein the matrix includes Bi₂Te₃. In certain embodiments, the embedded precipitates include In₂Te₃. In certain embodiments, the length of the embedded precipitates is between 10 nm and 20 μm. In some embodiments, the thickness of the embedded precipitates is between 10 nm and 2 μm. In various embodiments, the space between the embedded precipitates is between 10 nm and 20 μm. In some embodiments, the article of manufacture further includes a dopant selected from the group consisting of Yb, Ce, Se, Sb, I, and Pb. In some embodiments, the article of manufacture includes a compound of the formula (Bi₁₋ₓInₓ)₂Te₃. In various embodiments, 0<x≦0.5. In certain embodiments, the thermoelectric figure of merit (zT) is at least 0.8 at 25° C.

In various embodiments, the invention teaches a method of manufacturing an article, including: (1) providing a quantity of elements, including Bi, Te, and In; (2) melting the elements; (3) quenching the elements, thereby forming an ingot; (4) annealing the ingot at a first annealing temperature; (5) quenching the ingot; and (6) annealing the ingot at a second annealing temperature, wherein the second annealing temperature is lower than the first annealing temperature. In some embodiments, the elements are melted at a temperature greater than the melting temperature of Bi₂Te₃ and In₂Te₃. In various embodiments, the elements are melted at a temperature between 600° C. and 1000° C. In various embodiments, the elements are melted for 8 to 16 hours. In certain embodiments, the first annealing temperature is between 500° C. and 600° C. In certain embodiments, the ingot is annealed at the first annealing temperature for 72 to 120 hours. In certain embodiments, the second annealing temperature is between 300° C. and 500° C. In various embodiments, the ingot is annealed at the second annealing temperature for 48 to 96 hours. In some embodiments, the method further includes doping the article with a dopant. In some embodiments, the dopant is selected from the group consisting of Yb, Ce, Se, Sb, I, and Pb.

In various embodiments, the invention teaches a method for using an article of manufacture in a thermoelectric device, wherein the article of manufacture includes a matrix including Bi₂Te₃, and embedded precipitates including In₂Te₃. In certain embodiments, the method includes applying a temperature gradient to the article of manufacture, and collecting electrical energy. In other embodiments, the invention includes applying electrical energy to the article of manufacture; and transferring heat from a first space at a first operation temperature to a second space at a second operation temperature, wherein the first operation temperature is lower than the second operation temperature. In various embodiments, the article of manufacture further includes a dopant. In certain embodiments, the dopant is selected from the group consisting of Yb, Ce, Se, Sb, I, and Pb.

### BRIEF DESCRIPTION OF THE DRAWINGS

Exemplary embodiments are illustrated in the referenced figures. It is intended that the embodiments and figures disclosed herein are to be considered illustrative rather than restrictive.

FIG. 1 depicts, in accordance with an embodiment of the invention, the pseudo-binary phase diagram of the Bi₂Te₃—In₂Te₃ system. Displayed are the compositions and temperatures for the isothermal annealing stages (filled circles) for homogenization and precipitation. Also shown is the expected solvus line (dashed) and solubilities (open circles) based on experimental results.

FIG. 2 depicts, in accordance with an embodiment of the invention, scanning electron microscopy (SEM) images of the synthesis route and resulting composite consisting of Bi₂Te₃ matrix with embedded In₂Te₃ precipitates (7 at. % In) when annealed at 555° C. for 96 h and water quenched (a), annealed at 500° C. for 72 h (b), annealed for 450° C. for 72 h (c), both with inset high-magnification image of structures formed during annealing.

FIG. 3 depicts, in accordance with an embodiment of the invention, the resulting histogram data for both the 500° C. sample (a,b) and the 450° C. sample (c,d) precipitate spacings and thicknesses after annealing for 72 h.

FIG. 4 depicts, in accordance with an embodiment of the invention, electron backscatter diffraction (EBSD) results for the Bi₂Te₃—In₂Te₃ composite. Inset on the top left of (a) is the resulting map based on the Euler angle of the incident diffraction, indicating the precipitate is a single grain. Also inset in (a) is an SEM image of the actual scan, and the main image is of the resulting diffraction based on composition with the dark color being Bi₂Te₃ and the lighter color (diagonal) being In₂Te₃. The pole figures can also be seen (b-e), indicating that the resulting diffraction is indeed {0 0 0 1} Bi₂Te₃∥{1 1 1} In₂Te₃ and consequently <1 1 2 0> Bi₂Te₃∥<1 1 0> In₂Te₃, thus aligning both the close-packed planes and directions.

FIG. 5 depicts, in accordance with an embodiment of the invention, reducing the lattice thermal conductivity while maintaining a constant carrier concentration directly improves the zT (moving from point (1) to (2)). A further improvement is achieved by reoptimizing the carrier concentration, bringing the peak zT to point (3). Semi-empirical model from data on Bi₂Te₃.

FIG. 6 depicts, in accordance with an embodiment of the invention, a backscattered SEM image of in-grain orientation of In₂Te₃ precipitates inside bulk Bi₂Te₃. This grain in particular is nearly 1 mm at its widest and it is clear that the precipitation has a distinctly favored orientation. The inset is a higher magnification image of the nanostructure indicating that the smallest dimension of the structure is sub-μm as is the spacing between precipitates.

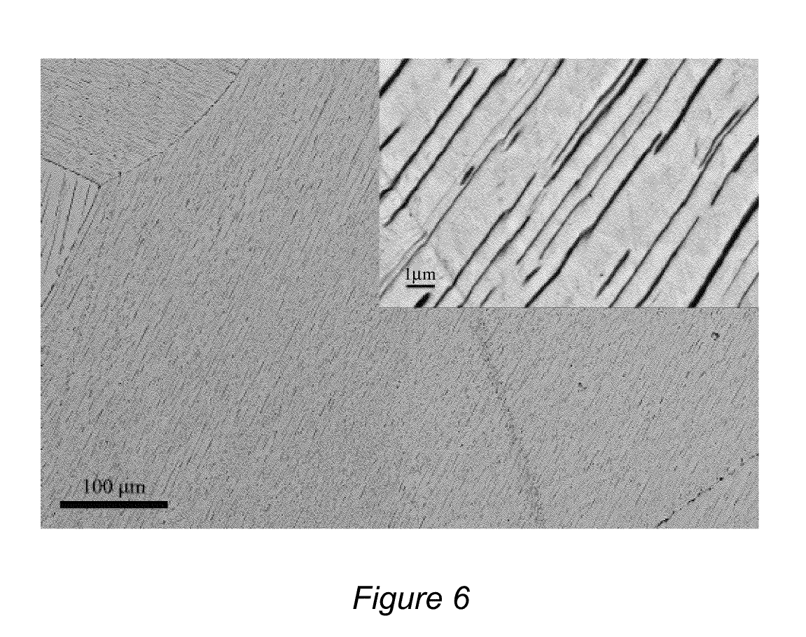

FIG. 7 depicts, in accordance with an embodiment of the invention, a backscattered SEM image of the resulting zone leveled and annealed oriented grain structure polycrystalline Bi₂Te₃—In₂Te₃ composite. The precipitates all take the same in grain orientation as in the non-zone leveled samples.

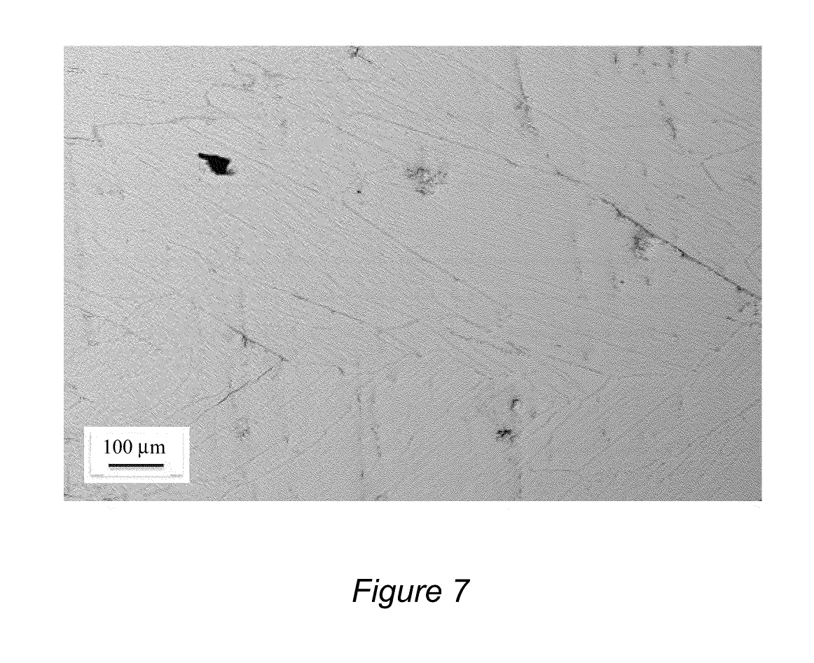

FIG. 8 depicts, in accordance with an embodiment of the invention, thermal diffusivity data for the resulting oriented composite of Bi₂Te₃ and In₂Te₃. As can be seen, there is a significant reduction to the thermal diffusivity, indicating that the addition of Indium significantly reduces the thermal conductivity of the material.

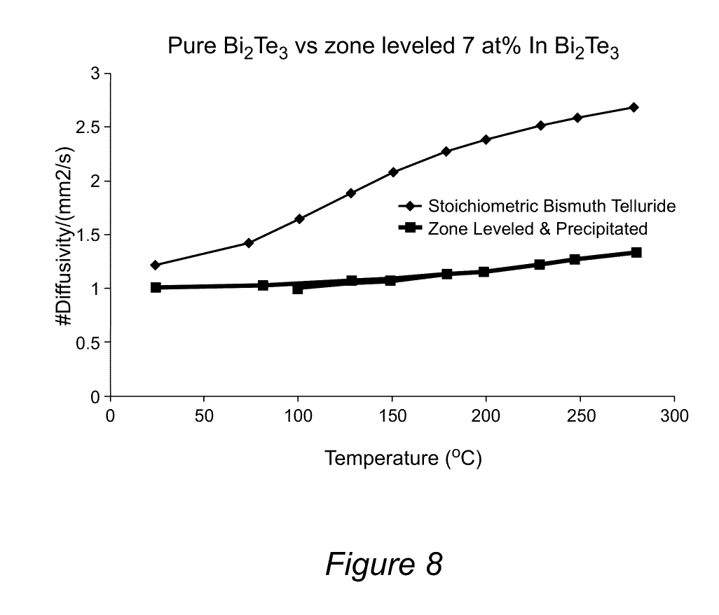

### DESCRIPTION OF THE INVENTION

All references cited herein are incorporated by reference in their entirety as though fully set forth. Unless defined otherwise, technical and scientific terms used herein have the same meaning as commonly understood by one of ordinary skill in the art to which this invention belongs.

In some embodiments, the numbers expressing quantities of ingredients, properties such as molecular weight, reaction conditions, and so forth, used to describe and claim certain embodiments of the application are to be understood as being modified in some instances by the term “about.” Accordingly, in some embodiments, the numerical parameters set forth in the written description and attached claims are approximations that can vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the application are approximations, the numerical values set forth in the specific examples are reported as precisely as practicable.

The inventors recently found that intrinsic, semiconducting Ag₂Te precipitates embedded in PbTe significantly reduce lattice thermal conductivity sufficient to increase zT to above 1.5, as demonstrated in Pei et al, Advanced Functional Materials, 21 p.241 (2011), which is incorporated herein by reference in its entirety as though fully set forth. This is achieved with nanoparticles approximately 100 nm in size, which reduce the lattice thermal conductivity an additional 20% beyond that expected from point defect scattering due to alloying. The inventors have demonstrated that 100 nm size, coherent (epitaxy-like) precipitates can be prepared by manipulating the known temperature dependent solubility found in pseudo-binary phase diagrams, as demonstrated in Ikeda et al, Acta Materialia 57 p.666 (2009), which is incorporated herein by reference in its entirety as though fully set forth.

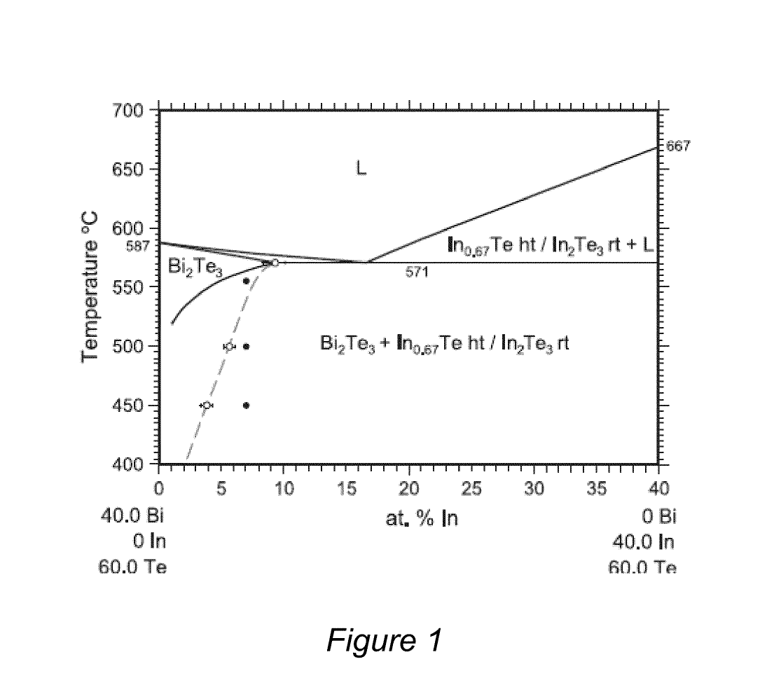

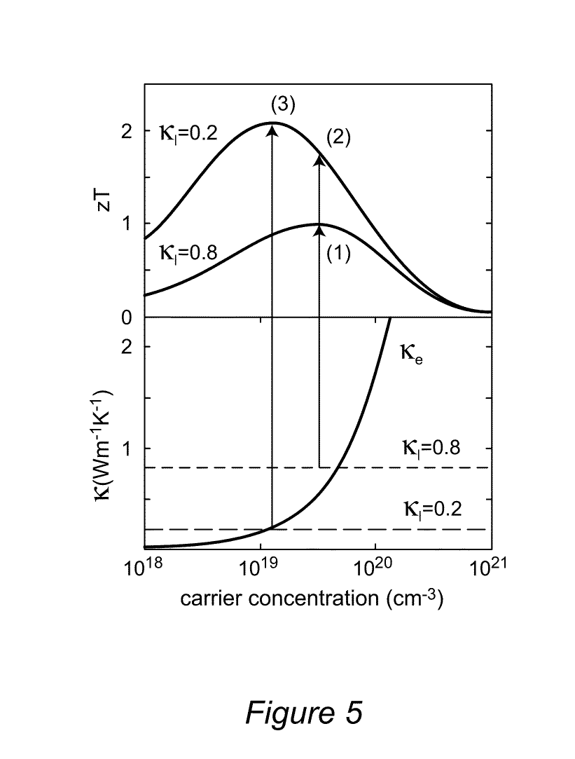

For Bi₂Te₃ the inventors found that the Bi₂Te₃—In₂Te₃ pseudo binary (FIG. 1) contains all the essential features for composite formation that were found in PbTe—Ag₂Te. The inventors determined that there is a solubility difference between high and low temperatures large enough that, upon cooling, coherent precipitates can be produced, similar to what they found in PbTe—Ag₂Te. The Indium solubility in Bi₂Te₃ is primarily substitutional for isovalent Bismuth, thus a low carrier concentration, intrinsic Bi₂Te₃ matrix can be made as the inventors found for PbTe—Ag₂Te but not Sb₂Te₃/PbTe. Further control over carrier concentration can be achieved by doping with +2 (e.g. Yb) and +4 (e.g. Ce) rare earth elements or the common dopants used in commercial Bi(Sb)₂Te₃. Even a modest reduction of 10-20% in lattice thermal conductivity would result in significant improvement, as lower K_{lattice} enables optimization at lower carrier concentration, raising overall zT (FIG. 5). Nevertheless, up to a 50% reduction in lattice thermal conduction should be possible with this method as the observed K_{lattice} in Bi₂Te₃ is over twice Kₘᵢₙ, which the inventors often approach with nano-composites.

Therefore, in some embodiments the invention teaches an article of manufacture including a matrix and embedded precipitates, wherein the matrix includes Bi₂Te₃. In some embodiments, the embedded precipitates include In₂Te₃. In some embodiments, at least one dimension of one or more of the embedded precipitates is between 10 nm and 20 μm in length. In some embodiments, at least one dimension of one or more of the embedded precipitates is between 100 nm and 5 μm in length. In some embodiments, the space between two or more of the embedded precipitates is between 10 nm and 20 μm in length. In some embodiments, one or more of the embedded In₂Te₃ precipitates are between 10 nm and 2 μm thick. In some embodiments, the embedded precipitates are relatively straight plate-like structures. In some embodiments, the embedded precipitates are ribbon-like structures. In various embodiments, the article of manufacture includes a compound of the formula (Bi₁₋ₓInₓ)₂Te₃, wherein 0≦x≦0.5. In various embodiments, x=0.175 (7 at. % In). In certain embodiments, the thermoelectric figure of merit (zT) of the article of manufacture is at least 0.8 at 25° C. In some embodiments, the article of manufacture further includes a dopant. In some embodiments, the dopant can include, but is in no way limited to, Yb, Ce, Se, Sb, I, and Pb.

In some embodiments, the invention teaches a method of manufacturing an article, including providing appropriate quantities of Bi, Te, and In. In some embodiments, stoichiometric amounts of Bi, Te and In are weighed out in order to attain a composition of (Bi₁₋ₓInₓ)₂Te₃, wherein 0≦x≦0.5. In an embodiment, x=0.175 (7 at. % In). In some embodiments, the starting elements are placed into a container and vacuum sealed to a pressure of between 10⁻⁶ Torr and 5e10⁻⁵ Torr. In some embodiments, the container is an amorphous silica ampoule. In some embodiments, the pressure is approximately 10⁻⁵ Torr. In certain embodiments, the sample is then melted at a temperature of between 600° C. and 1000° C. In various embodiments, the sample is melted at a temperature of 800° C. In some embodiments, the sample is melted for between 8 hours and 16 hours. In some embodiments, the sample is melted for 12 hours. In some embodiments, the sample is melted in a vertical tube furnace. In some embodiments, the sample is then water quenched. In some embodiments, the resulting ingot is then annealed at between 500° C. and 600° C. for between 72 hours and 120 hours, and water quenched again. In certain embodiments, the annealing temperature for this step is 555° C. and the duration is 96 hours. In some embodiments, the resulting ingot is then annealed a final time at between 300° C. and 500° C. for between 48 hours and 96 hours. In some embodiments, the final annealing step is performed at 500° C. for 72 hours. In some embodiments, the final annealing step is performed at greater than 500° C. In some embodiments, the final annealing step is performed at 450° C. for 72 hours.

In some embodiments, the method further includes doping the article with a dopant. In certain embodiments, the dopant can include, but is in no way limited to, Yb, Ce, Se, Sb, I, and Pb. In various embodiments, the methods of manufacturing described herein yield an article of manufacture described herein.

In various embodiments, the invention teaches a method of using an article of manufacture in a thermoelectric device, wherein the article of manufacture includes any of the articles of manufacture described herein. In some embodiments, the article of manufacture includes a composition of the formula (Bi₁₋ₓInₓ)₂Te₃, wherein 0≦x≦0.5. In an embodiment, x=0.175 (7 at. % In). In some embodiments, the article of manufacture is doped, as described above. In some embodiments, the method includes applying a temperature gradient to the article of manufacture, and collecting electrical energy. In various embodiments, the invention teaches applying electrical energy to the article of manufacture; and transferring heat from a first space at a first operation temperature to a second space at a second operation temperature, wherein the first operation temperature is lower than the second operation temperature. In some embodiments, the thermoelectric materials (articles of manufacture) described in the present invention are used in solid-state refrigeration. In some embodiments, the thermoelectric materials described in the present invention are used for low-temperature waste heat recovery.

One skilled in the art will recognize many methods and materials similar or equivalent to those described herein, which could be used in the practice of the present invention. Indeed, the present invention is in no way limited to the methods and materials described.

### EXAMPLES

### Experiments I

### Example 1

### Introduction—Formation of Highly Oriented Large Nanoscale In₂Te₃ Precipitates in Bulk Bi₂Te₃

While it is clear that electrons affect every aspect of zT, efforts have recently been made to reduce the lattice thermal conductivity in the field via bulk nanostructuring using a number of methods. The reduction is believed to occur due to the boundary scattering at the interfaces of the two materials, where orientation and surface roughness play very important roles. In addition, it is important to reduce the heat transport due to phonons, without severely affecting the mobility of electrons in the material. Therefore, a sensible design is to start with a material system that already has an appealing power factor (S²σ), but also a thermal conductivity that is above the expected minimum. As described herein, in one aspect of the invention, the inventors focused on the classic room temperature thermoelectric material Bi₂Te₃, typically used in solid-state refrigeration, but also in low-temperature waste heat recovery.

In past works, it was thought that the only significant Kₗ reductions were due to structures that were on the order of a few nanometers in thickness and spacing. However, recently evidence has been produced that one can achieve reductions in Kₗ for structures that are significantly larger (˜100-1000 nm). This is believed to be due to the frequency dependence of the parameters that make up the lattice thermal conductivity, specifically in this case the phonon mean free path. Therefore, rather than gauge the ability to reduce Kₗ by a single structure size scale, having distributions in both thickness and spacing corresponding to the spectrum of mean free paths could enhance zT through significant reductions to Kₗ via increased boundary scattering.

To reduce K₁ in this study, the inventors employ a thermodynamically driven nucleation and growth end member precipitation method where the solubility dependence on temperature (FIG. 1) is exploited to reduce the phonon mean free paths for thermoelectric applications. Studies of nanocomposite structure formation via phase transformations are limited and prior work in this material system has focused mainly on the maximum solubility of In in Bi₂Te₃. However, there has been little work examining the solubility below the eutectic temperature, specifically in establishing the solvus line. In an effort to control the microstructure for thermoelectric applications, the inventors investigated the phase diagram below the eutectic temperature, and also established a synthesis regime for equilibrium composite formation intended for thermoelectric applications.

### Example 2

### Methods

Stoichiometric amounts of Bi, Te and In were weighed out in order to attain a composition of (Bi₁₋ₓInₓ)₂Te₃ with x=0.175 (7 at. % In). The starting elements were placed in amorphous silica ampoules and vacuum sealed to a pressure of ˜10⁻⁵ Torr. The samples were then placed in a vertical tube furnace and melted well above the melting temperature of both Bi₂Te₃ and In₂Te₃, in this case 800° C. (FIG. 1) and water quenched. The resulting ingot was then annealed in the solid-solution region at 555° C. for 96 h and water quenched again. Finally, the ingot was annealed in the lower-temperature two-phase region at either 500 or 450° C. for 72 h in order to exploit the decrease in solubility of In₂Te₃ with temperature.

Upon completing the synthesis, the ingots were cut longitudinally for microscopic examination. The resulting face was polished with SiC paper ranging in grit ratings from #240 to #800, then polished with 3 μm, 1 μm, and 0.3 μm Al₂O₃ particles; a final polishing with colloidal silica (0.05 μm) particles was used for nanostructure observations. A field emission scanning electron microscope (Zeiss LEO 1550 VP) with a backscattered electron and secondary electron detector with an accelerating voltage of 20 kV was used to make the observations. Image analysis was done using image-processing software (ImageJ) to first convert to binary images and then collect thickness and spacing data.

The crystal orientation relationships were established via electron backscatter diffraction (EBSD; HKL Technology, Inc.), again, with an operating voltage of 20 kV. The sample was tilted 70° with respect to the horizontal axis in the microscope in order to properly collect EBSD data. Backscatter patterns were collected and analyzed using the software package provided by Channel5™ (HKL Technology, Inc.). In doing the analysis, crystallographic information for both tetradymite structured Bi₂Te₃ (rhombohedral crystal with space group R3m) and cubic ZnS structured In₂Te₃ (cubic crystal with space group F43m) were used. Chemical analysis was done using energy dispersive X-ray spectroscopy (EDS) and the INCA software package was used for collection of spectra and data analysis. In addition, it should be noted that when EDS was done on precipitates in this study, the spatial resolution is ˜1 μm, and therefore only precipitates that were a minimum of 1 μm in thickness were used for these measurements.

### Example 3

Results and Discussion

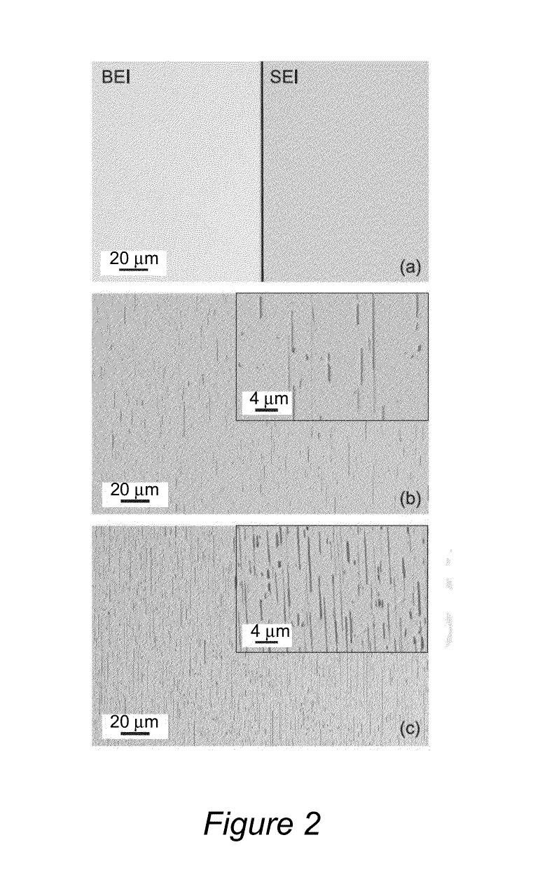

SEM images were taken of each sample after the homogenization and precipitation steps in order to quantify the extent to which homogenization and precipitation of the samples had occurred (FIG. 2). After each step, both a backscattered electron image (BEI) and a secondary electron image (SEI) were taken in order to see the contrast from the differing Z values with the backscattered detector and then to confirm that the contrast seen in the backscattered images was not due to surface artifacts, i.e. cracks or holes.

FIG. 2a contains both a split BEI and SEI displaying the homogeneous solid solution of 7 at. % In in Bi₂Te₃. According to the reported phase diagram (FIG. 1), however, this composition and temperature is not in the single-phase solid-solution region. Moreover, there is no phase diagram information below ˜520° C. in the literature. Overlaid is a more probable solvus line based on isothermal annealing experiments done in this study. As can be seen in FIGS. 2b and c, precipitation occurs when the temperature of the ingot is decreased to either 500° C. or 450° C. due to the decrease in solubility of In with decreasing temperature. Crystals were grown via directional solidification using the Bridgman method in order to determine the maximum solubility, and isothermal annealing techniques were used to determine the solubility at 500° C. and 450° C.

In order to determine the degree to which nucleation is complete, it is necessary to know the diffusion length, \sqrt{Dt}, where D is the diffusion coefficient and t is the time scale involved. Due to the soft impingement effect, it is expected that when the precipitate spacing is less than \sqrt{Dt}, nucleation, from a number density standpoint, is expected to be complete. Unfortunately there is no diffusion information for either In or In₂Te₃ in Bi₂Te₃. However, as can be seen in Table 1, there exists diffusion coefficient information, both parallel and perpendicular to the basal planes, for several transition metals in Bi₂Te₃.

TABLE 1
Diffusion coefficients of transition metals in Bi₂Te₃ at T = 450° C.
for t = 72 h from the literature. For the cases of Ag and Au,
the extremities of the expressions for D_{∥} and D_{⊥} were
calculated, and the average of those values was taken and
used in the comparison. Diffusion coefficients for the 500° C.
samples are larger, and are therefore are not displayed here.

| Metal | \sqrt{D ∥ t} (cm) | \sqrt{D ⊥ t} (cm) |
|---|---|---|
| Cu | 5.59 | 0.22 |
| Ag | 1.05 | 0.023 |
| Au | 3.61 | 0.36 |

Based on this information it is expected that 72 h is adequate time to achieve complete nucleation as the largest spacing between precipitates is ˜20 μm and the characteristic diffusion lengths, as seen in Table 1, for the transition metals considered are all considerably larger than this spacing. The compositions of the homogeneous, precipitated and Bridgman-grown samples can be seen in Table 3. The composition of the homogeneous sample (555° C.) was nominal with respect to the calculated value, and the high (˜9 at. %) solubility of In in Bi₂Te₃ was verified.

Ideally the matrix and precipitate compositions would be corroborated using the equilibrium phase diagram, FIG. 1; however, that is not possible in this case because the phase diagram has never been examined at temperatures below 520° C. In order to prove that the precipitation occurs due to the decrease in the solubility with decreasing temperature, the solvus line was investigated. The same criterion for the diffusion length can also be used to determine when the equilibrium composition has been reached, and in the case of a 72 h annealed sample, it would seem the equilibrium composition had been attained for both samples.

However, the samples were annealed at their respective isotherms for an additional 72 h, the composition was examined, and the resulting composition did not change. This gives qualitative insight into the location of the solvus line shown on the phase diagram generated in FIG. 1. The resulting matrix composition of In is ˜4 at. % at 450° C. and increases with increasing temperature up to ˜9 at. % at the eutectic temperature, as was determined by the Bridgman method (Table 3). While not wishing to be bound by any one particular theory, from a compositional stability standpoint, it would appear that precipitation is complete within the time scale of 72 h.

There still exists the issue of coarsening with regard to prolonged annealing. Since the compositional stability seems stable after an additional 72 h at both 500° C. and 450° C., it is expected to be minimal. In addition, the application temperature for this material is significantly lower (maximum ˜250° C.) than both precipitation isotherms, so it is unlikely that once the composite is formed it would experience an environment well above room temperature.

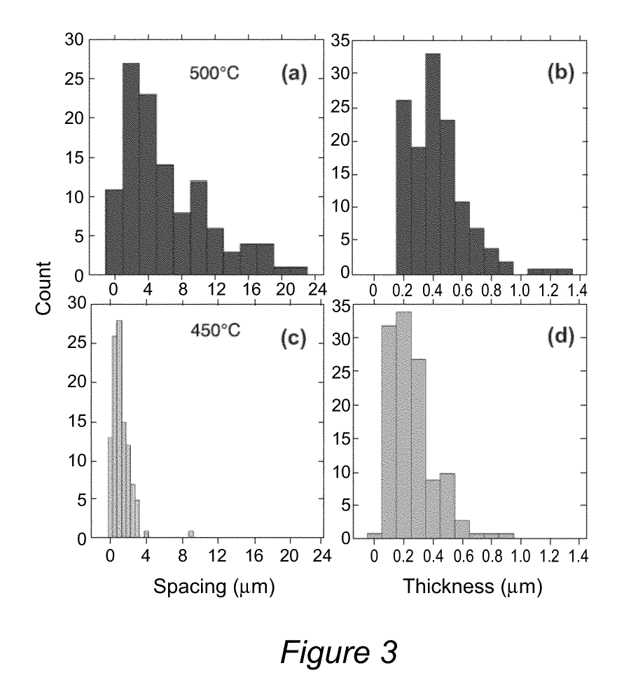

Based on the 2-D SEM images taken, it appears as if the precipitates form long and straight plate-like or possibly ribbon-like structures. As can be seen in FIGS. 2b and 2c and FIG. 3, the observed thickness of the In₂Te₃ precipitates in both samples ranges an order of magnitude from ˜100 to ˜1000 nm. Even though the distribution of thicknesses spans a similar length scale, the peak thickness value for the 450° C. sample is ˜50% less (200 nm) than that of the 500° C. sample (400 nm). The spacing of precipitates, however, is significantly different in each sample as the 500° C. sample ranges from ˜1 to ˜20 μm while the 450° C. sample ranges from 0.1 to 5 μm.

The decrease in thickness and spacing with decreasing temperature can be qualitatively described from classic nucleation theory of diffusive phase transformations. The critical free energy barrier, ΔF*, to permit nucleation for spherical nuclei is expressed by:

$$Δ {F}^{*} = \frac{16}{3} \frac{{πσ}^{3}}{{( Δ {F}_{c} + Δ {F}_{E} )}^{2}} , \qquad ( 1 )$$

where σ is the interfacial energy, ΔF_{c} is the chemical driving force and ΔF_{E} is the strain energy. The critical free energy dictates the rate, I, of nuclei formation represented by:

$$I = {NA}^{*} v exp ( - \frac{Δ {F}_{A} + Δ {F}^{*}}{{k}_{B} T} ) \qquad ( 2 )$$

where N is the number of atomic sites per volume, A* is the number of sites on the surface of the critical nucleus, v is the atomic vibration frequency, and ΔF_{A} is the activation energy of atomic jumps across the interface. The lower annealing temperature acts to increase the supercooling and supersaturation, ultimately increasing the chemical driving force for nucleation. The large chemical driving force decreases the critical energy for nucleation, Eq. (1), which increases the nucleation rate, Eq. (2), and tends to result in a larger number density of precipitates. The higher supersaturation is indicated by an increased volume fraction with decreasing temperature, as seen in Table 2.

The volume fraction of In₂Te₃ for the 7 at. % In Bi₂Te₃ samples at both 500 C and 450 C can be calculated by applying the lever rule to the EDS measurements and the average thicknesses and spacings

$$( {X}_{vol} = \frac{thickness}{spacing} )$$

from FIG. 3. The large uncertainties in the lever rule calculations stem from the error in chemical compositions by EDS (Table 3). The error in thickness and spacing due to the SEM parameters when imaging, and also due to the image analysis of the resulting micrographs are difficult to quantify, but an estimated error of ±20% for the average thickness and spacing for each temperature was used.

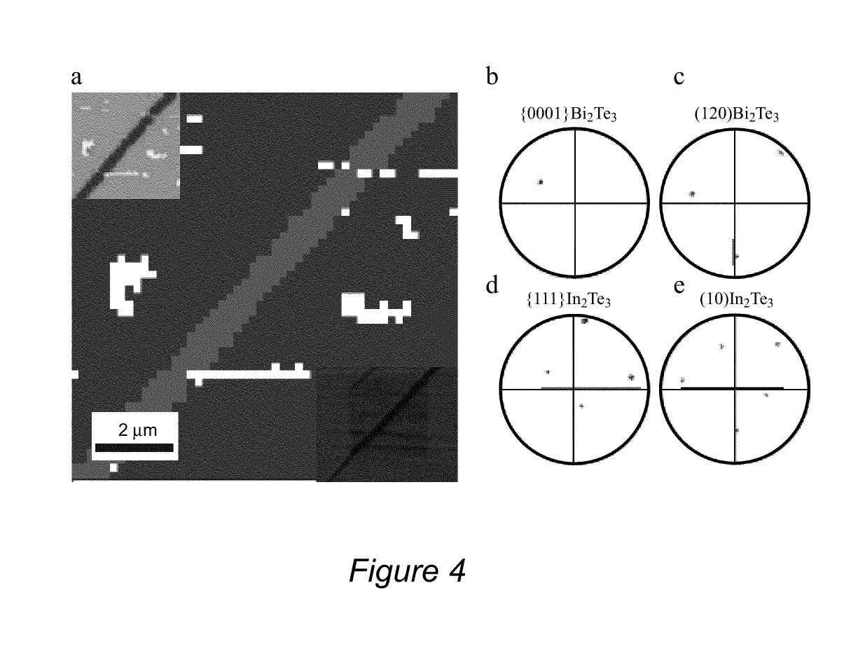

It should be noted that these are not the true thicknesses and spacings, as the observation plane is most likely inclined relative to the direction normal to the precipitates (FIG. 4). These size scales make sense from a solid-state reaction point of view, as the slow diffusion in the solid, compared to the diffusion in the liquid state, should allow at least one dimension of the precipitates to be small. Adding to this is the fact that the in-plane and cross-plane diffusion coefficients are widely different (Table 1). Furthermore, the energies at the edge and broad interfaces should be different due to the difference in coherency and or atomic species involved in bonding. It is due to these dependencies that a high aspect ratio should be expected in these precipitates.

TABLE 2
Volume fraction data for 7 at. % In Bi₂Te₃
samples at both 500 C. and 450° C. as calculated
by applying the lever rule to the EDS measurements and
$from the average thickness and spacing data ( {X}_{vol} = \frac{thickness}{spacing} ) .$

| Method | 500° C. (%) | 450° C. (%) |
|---|---|---|
| Lever rule | 4.1 ± 3.6 | 9.6 ± 3.2 |
| Xᵥₒₗ | 6.8 ± 1.5 | 17.7 ± 7.4 |

TABLE 3
Energy dispersive X-ray spectroscopy (EDS) data for samples
of interest homogenized at 555° C. for 96 h, annealed at 500 C and
450° C. for 72 h (FIG. 2), and also the Bridgman-grown crystal.
All precipitates measured in the precipitated sample had
a minimum thickness of ~1 μm for accurate measurements.
Likewise, matrix areas where the largest precipitate
spacing occurred was utilized for the same purpose.

| Sample | In (at. %) | Bi (at. %) | Te (at. %) |
|---|---|---|---|
| Bridgman | 9.0 ± 1.0 | 30.5 ± 0.5 | 60.3 ± 0.6 |
| 555° C. | 7.6 ± 1.0 | 32.7 ± 0.4 | 59.8 ± 0.8 |
| 500° C. Mat. | 5.9 ± 1.4 | 32.0 ± 2.0 | 63.0 ± 2.0 |
| 450° C. Mat. | 4.4 ± 1.2 | 35.3 ± 1.4 | 60.2 ± 1.0 |
| 500° C. Precip. | 35.0 ± 6.0 | 4.0 ± 6.0 | 61.0 ± 1.0 |
| 450° C. Precip. | 32.0 ± 2.0 | 4.0 ± 0.9 | 59.7 ± 0.8 |

In any particular grain, the structures have a monovariant orientation. As can be seen in FIGS. 2b and 2c, every ingrain precipitate is aligned in the same orientation, in this case with the primary growth direction vertical. This type of orientation generally stems from the minimization of strain and interfacial energies upon structure formation, which will usually have a specific set of preferred crystallographic orientations. For example, in the PbTe—Ag₂Te system the precipitates align along the {100} planes in PbTe to maintain the Te sublattice between the two crystals, and in PbTe—Sb₂Te₃ the crystals take on a standard face-centered cubic/hexagonal close-packed orientation of {1 1 1} PbTe∥{0 0 0 1} Sb₂Te₃, aligning the close-packed planes.

Similarly, in the PbTe—PbBi₂Te₄ system the orientation relationship is {1 1 1} PbTe∥{0 0 0 1} PbBi₂Te₄. Because of the similarities in the PbTe—Sb₂Te₃ and PbTe—PbBi₂Te₄ systems to Bi₂Te₃—In₂Te₃, it is reasonable to expect a comparable orientation relationship, and as can be seen in FIG. 4, the relationship is indeed {0 0 0 1} Bi₂Te₃∥{1 1 1} In₂Te₃ with the habit plane of the precipitates along {0 0 0 1} Bi₂Te₃. Also, like the PbTe—Sb₂Te₃ and PbTe—PbBi₂Te₄ systems, the close-packed <1 1 2 0> Bi₂Te₃∥<110> In₂Te₃ directions are aligned in this study as well.

It should be noted that the exact crystal structure of In₂Te₃ at the temperatures used in this study can take one of several different forms. In the literature, the crystal structure of In₂Te₃ is complicated; however, the one aspect past authors have been able to agree on is that the crystal structure has a Te sublattice for compositions in the range of 57-61% Te. This Te sublattice takes on an fcc structure and the ordering or disordering of In and its vacancies has not been fully examined. Due to this complex metal/vacancy distribution for the possible phases of In₂Te₃, and also the residual Bi content dissolved in the material affecting the lattice parameter, EBSD results were sometimes difficult to analyze. However, due to the fact that the differing crystallographic results often stem from In ordering/disordering, it is not believed this should affect the orientation relationship.

Since it has been established that large nanoscale structures can be formed in Bi₂Te₃, the next step would be to determine the extent to which the composite formation can affect the transport properties. If the most generic kinetic expression for thermal conductivity is used, Kₗ=⅓Cvl where C is the specific heat, v is the phonon velocity and l is the mean free path, the parameter with the highest probability of reduction from the nanocomposite formation will be the mean free path. Altering C and v involves altering the phonon dispersion, which would require some type of bond strength alteration. Also, due to the inherent anisotropy in the crystal structure of Bi₂Te₃, it will be necessary to determine which direction will give the best materials efficiency, zT.

As far as thermal conductivity is concerned, it will be a matter of considering either the in-plane (along the major growth direction of the precipitates) or cross-plane (perpendicular to the major growth direction) conductivity. Due to the fact that in most high figure of merit versions of Bi₂Te₃, the transport properties are best optimized perpendicular to the <0001> direction, it would therefore be expected that the in-plane conductivity is the parameter that needs to be considered. In thinking about the in-plane conductivity, the calculations approximate the materials as superlattices, and in the case of the Bi₂Te₃—In₂Te₃ system this should be an adequate approximation. In these calculations, there are two main parameters which affect the resulting decrease in thermal conductivity, namely interfacial roughness and structure periodicity. As important as reducing Kₗ is to maintain a large zT, it is just as important to disrupt the electrical material properties as little as possible. This is where having coherent matrix—precipitate interfaces with few interfacial dislocations can prove beneficial. The dislocations act as carrier scattering centers for the electrons, decreasing the electronic carrier mobility. However, the coherency strain can enhance the phonon scattering, which can further reduce Kₗ.

An indication that nanostructuring Bi₂Te₃ with In₂Te₃ will maintain its high electron mobility is the fact that due to the strict orientation of the precipitates in the matrix, the interfaces are expected to be either coherent or semicoherent. The main coherency indicator is the low lattice mismatch. Dislocation density behaves proportionally to lattice mismatch: hence the smaller the mismatch, the lower the dislocation density and the more coherent the interface. In the case of Bi₂Te₃—In₂Te₃ the lattice mismatch as calculated by

$$ε = [ \frac{{a}_{h} \sqrt{2}}{{a}_{c}} - 1 ] ,$$

where ε is the mismatch percent and aₕ=4.395 Å and a_{c}=6.158 Å are the lattice parameters of the hexagonal and cubic crystals, is only ˜1%.

From literature data, In is not expected to be a strong dopant in Bi₂Te₃. Despite the fact that at high concentrations (˜4 at. %) the conductivity type changes from p-type to n-type, the Hall coefficient remains less than unity for concentrations up to the solubility limit of ˜10 at. %, so it would be expected that this composite could be doped either n-type or p-type using traditional dopants (e.g. Sb and Se). However, due to the anisotropy in the crystal structure, it would be necessary at least to obtain an oriented polycrystalline sample, or better yet, single crystals of the composite, to truly understand the fundamentals behind the change in transport properties. Moreover, strict understanding of the pseudobinary phase diagram will be necessary before single-crystal growth techniques can be utilized. Likewise, through this understanding of the equilibrium phase diagram it will be possible to finely tune the nanostructures to better suit thermoelectric applications. Studies controlling the volume fraction and number density of precipitates and also the solubilities of In for different temperatures and concentrations will need to be carried out.

### Example 4

### Conclusion

A successful synthesis regime was determined to grow highly oriented plate-like In₂Te₃ nanostructures inside bulk thermoelectric Bi₂Te₃ using a thermodynamically driven nucleation and growth technique. This technique utilized the decreasing solubility of In with decreasing temperature in Bi₂Te₃. The maximum solubility of In in Bi₂Te₃ was verified by unidirectional solidification using the Bridgman technique. An experimental solvus line was determined based on isothermal annealing experiments at two temperatures (500° C. and 450° C.) below the eutectic temperature. The average thickness and spacing is ideal for the reductions in thermal conductivity necessary for efficient thermo-electric materials. The orientation relationship between the two crystals aligns the close-packed planes, or {0001} Bi₂Te₃∥{1 1 1} In₂Te₃, and also the close-packed directions, or <1120> Bi₂Te₃∥<110> In₂Te₃ with the precipitates' habit plane along {0001} Bi₂Te₃. This system is a promising nanostructuring candidate because of the low Hall coefficient for high levels of In, as the Bi₂Te₃—In₂Te₃ composite should behave like an intrinsic semiconductor, with the expectation that n-type or p-type conductivity should be attainable.

The various methods and techniques described above provide a number of ways to carry out the application. Of course, it is to be understood that not necessarily all objectives or advantages described can be achieved in accordance with any particular embodiment described herein. Thus, for example, those skilled in the art will recognize that the methods can be performed in a manner that achieves or optimizes one advantage or group of advantages as taught herein without necessarily achieving other objectives or advantages as taught or suggested herein. A variety of alternatives are mentioned herein. It is to be understood that some preferred embodiments specifically include one, another, or several features, while others specifically exclude one, another, or several features, while still others mitigate a particular feature by inclusion of one, another, or several advantageous features.

Furthermore, the skilled artisan will recognize the applicability of various features from different embodiments. Similarly, the various elements, features and steps discussed above, as well as other known equivalents for each such element, feature or step, can be employed in various combinations by one of ordinary skill in this art to perform methods in accordance with the principles described herein. Among the various elements, features, and steps some will be specifically included and others specifically excluded in diverse embodiments.

Although the application has been disclosed in the context of certain embodiments and examples, it will be understood by those skilled in the art that the embodiments of the application extend beyond the specifically disclosed embodiments to other alternative embodiments and/or uses and modifications and equivalents thereof.

In some embodiments, the terms “a” and “an” and “the” and similar references used in the context of describing a particular embodiment of the application (especially in the context of certain of the following claims) can be construed to cover both the singular and the plural. The recitation of ranges of values herein is merely intended to serve as a shorthand method of referring individually to each separate value falling within the range. Unless otherwise indicated herein, each individual value is incorporated into the specification as if it were individually recited herein. All methods described herein can be performed in any suitable order unless otherwise indicated herein or otherwise clearly contradicted by context. The use of any and all examples, or exemplary language (for example, “such as”) provided with respect to certain embodiments herein is intended merely to better illuminate the application and does not pose a limitation on the scope of the application otherwise claimed. No language in the specification should be construed as indicating any non-claimed element essential to the practice of the application.

Preferred embodiments of this application are described herein, including the best mode known to the inventors for carrying out the application. Variations on those preferred embodiments will become apparent to those of ordinary skill in the art upon reading the foregoing description. It is contemplated that skilled artisans can employ such variations as appropriate, and the application can be practiced otherwise than specifically described herein. Accordingly, many embodiments of this application include all modifications and equivalents of the subject matter recited in the claims appended hereto as permitted by applicable law. Moreover, any combination of the above-described elements in all possible variations thereof is encompassed by the application unless otherwise indicated herein or otherwise clearly contradicted by context.

All patents, patent applications, publications of patent applications, and other material, such as articles, books, specifications, publications, documents, things, and/or the like, referenced herein are hereby incorporated herein by this reference in their entirety for all purposes, excepting any prosecution file history associated with same, any of same that is inconsistent with or in conflict with the present document, or any of same that may have a limiting affect as to the broadest scope of the claims now or later associated with the present document. By way of example, should there be any inconsistency or conflict between the description, definition, and/or the use of a term associated with any of the incorporated material and that associated with the present document, the description, definition, and/or the use of the term in the present document shall prevail.

In closing, it is to be understood that the embodiments of the application disclosed herein are illustrative of the principles of the embodiments of the application. Other modifications that can be employed can be within the scope of the application. Thus, by way of example, but not of limitation, alternative configurations of the embodiments of the application can be utilized in accordance with the teachings herein. Accordingly, embodiments of the present application are not limited to that precisely as shown and described.

What is claimed is:

1. An article of manufacture comprising a matrix and embedded precipitates, wherein the matrix comprises Bi₂Te₃.

2. The article of manufacture of claim 1, wherein the embedded precipitates comprise In₂Te₃.

3. The article of manufacture of claim 2, wherein the length of the embedded precipitates is between 10 nm and 20 μm.

4. The article of manufacture of claim 2, wherein the thickness of the embedded precipitates is between 10 nm and 2 μm.

5. The article of manufacture of claim 2, wherein the space between the embedded precipitates is between 10 nm and 20 μm.

6. The article of manufacture of claim 1, further comprising a dopant selected from the group consisting of Yb, Ce, Se, Sb, I, and Pb.

7. The article of manufacture of claim 1, comprising a compound of the formula (Bi₁₋ₓInₓ)₂Te₃.

8. The article of manufacture of claim 7, wherein 0<x≦0.5.

9. The article of manufacture of claim 1, wherein the thermoelectric figure of merit (zT) is at least 0.8 at 25° C.

10. A method of manufacturing an article, comprising:
providing a quantity of elements, comprising Bi, Te, and In;
melting the elements;
quenching the elements, thereby forming an ingot;
annealing the ingot at a first annealing temperature;
quenching the ingot; and
annealing the ingot at a second annealing temperature, wherein the second annealing temperature is lower than the first annealing temperature.

11. The method of claim 10, wherein the elements are melted at a temperature greater than the melting temperature of Bi₂Te₃ and In₂Te₃.

12. The method of claim 10, wherein the elements are melted at a temperature between 600° C. and 1000° C.

13. The method of claim 10, wherein the elements are melted for 8 to 16 hours.

14. The method of claim 10, wherein the first annealing temperature is between 500° C. and 600° C.

15. The method of claim 14, wherein the ingot is annealed at the first annealing temperature for 72 to 120 hours.

16. The method of claim 10, wherein the second annealing temperature is between 300° C. and 500° C.

17. The method of claim 16, wherein the ingot is annealed at the second annealing temperature for 48 to 96 hours.

18. The method of claim 10, further comprising doping the article with a dopant.

19. The method of claim 18, wherein the dopant is selected from the group consisting of Yb, Ce, Se, Sb, I, and Pb.

20. A method for using an article of manufacture in a thermoelectric device, wherein the article of manufacture comprises a matrix comprising Bi₂Te₃, and embedded precipitates comprising In₂Te₃.

21. The method of claim 20, comprising applying a temperature gradient to the article of manufacture, and collecting electrical energy.

22. The method of claim 20, comprising applying electrical energy to the article of manufacture; and transferring heat from a first space at a first operation temperature to a second space at a second operation temperature, wherein the first operation temperature is lower than the second operation temperature.

23. The method of claim 20, wherein the article of manufacture further comprises a dopant.

24. The method of claim 23, wherein the dopant is selected from the group consisting of Yb, Ce, Se, Sb, I, and Pb.
